(19) United States
(12) Patent Application Publication
(10) Pub. No.: US 2022/0231063 A1
(43) Pub. Date: Jul. 21, 2022

(54) IMAGE SENSOR

(71) Applicant: SAMSUNG ELECTRONICS CO., LTD., Suwon-si (KR)

(72) Inventors: YOUNGWOO CHUNG, Yongin-si (KR); Sooeon KIM, Seoul (KR); Hanseok KIM, Seoul (KR); Heegeun JEONG, Suwon-si (KR)

(21) Appl. No.: 17/646,860

(22) Filed: Jan. 3, 2022

(30) Foreign Application Priority Data
Jan. 18, 2021 (KR) 10-2021-0006944

(51) Int. Cl. H01L 27/146

(52) U.S. Cl. CPC H01L 27/14621; H01L 27/14636; H01L 27/14627

(57) ABSTRACT

An image sensor includes a substrate that includes a pixel regions; an insulating structure on the substrate; a grid pattern structure on the insulating structure; color filters on the insulating structure; and microlenses on the color filters. The grid pattern structure includes a first pattern portion and second pattern portions. The first pattern portion includes a first material pattern on the insulating structure, and a second material pattern on the first material pattern. The first material pattern is formed of a first material, and the second material pattern and the second pattern portions are formed of a second material. The first pattern portion includes parallel first horizontal straight portions, and parallel first vertical straight portions, and each of the second pattern portions includes a second horizontal straight portion parallel to the first horizontal straight portions and a second vertical straight portion parallel to the first vertical straight portions.

### CROSS-REFERENCE TO RELATED APPLICATION(S)

This application claims priority under 35 U.S.C. 119 from Korean Patent Application No. 10-2021-0006944, filed on Jan. 18, 2021 in the Korean Intellectual Property Office, the contents of which are herein incorporated by reference in their entirety.

### BACKGROUND

### Technical Field

The present inventive concept relates to an image sensor.

### Discussion of the Related Art

Image sensors that capture images and convert the images into electrical signals can be used not only in electronic devices for general consumers, such as digital cameras, mobile phone cameras, portable camcorders, etc., but also cameras installed in vehicles, security devices, or robots, etc. Since the image sensors can be miniaturized and should have high resolution, research has been conducted to meet these needs.

### SUMMARY

An embodiment of the present inventive concept provides an image sensor that has increased resolution.

According to an embodiment of the present inventive concept, an image sensor includes a first chip structure that includes a first substrate; and a second chip structure disposed on the first chip structure. The second chip structure includes: a second substrate that has a first surface that faces the first chip structure and a second surface opposite to the first surface; photoelectric conversion devices disposed in the second substrate; an insulating structure disposed on the second surface of the second substrate; a grid pattern structure disposed on the insulating structure; color filters disposed on the insulating structure and the grid pattern structure; and microlenses disposed on the color filters. The grid pattern structure includes a first pattern portion and second pattern portions, where the first pattern portion includes a first material pattern and a second material pattern disposed on the first material pattern. The first material pattern is formed of a first material, the second pattern portions and the second material pattern are formed of a second material that differs from the first material, and a center of each of the microlenses does not overlap the second pattern portions.

According to an embodiment of the present inventive concept, an image sensor includes a substrate that includes a plurality of pixel regions; an insulating structure disposed on the substrate and that includes a plurality of sequentially stacked layers; a grid pattern structure disposed on the insulating structure; color filters disposed on the insulating structure; and microlenses disposed on the color filters. The grid pattern structure includes a first pattern portion and second pattern portions. When viewed in a plan view, the first pattern portion includes first horizontal straight portions that are parallel to each other, and first vertical straight portions that are parallel to each other and perpendicular to the first horizontal straight portions, each of the second pattern portions includes a second horizontal straight portion parallel to the first horizontal straight portions, and a second vertical straight portion parallel to the first vertical straight portions, and the second horizontal straight portion is perpendicular to the second vertical straight portion.

According to an embodiment of the present inventive concept, an image sensor includes a substrate that includes a plurality of first pixel regions, a plurality of second pixel regions, and a plurality of third pixel regions; an insulating structure disposed on the substrate and that includes a plurality of sequentially stacked layers; a grid pattern structure disposed on the insulating structure; color filters disposed on the insulating structure; and microlenses disposed on the color filters. The color filters include a first color filter of a first color, a second color filter of a second color that differs from the first color, and a third color filter of a third color that differs from the first and second colors. The grid pattern structure includes a first pattern portion and second pattern portions, the first pattern portion is disposed between color filters of different colors of the first to third color filters, and the first to third color filters cover side surfaces and an upper surface of the second pattern portions. The microlenses include a plurality of microlenses disposed on the first color filter, a plurality of microlenses disposed on the second color filter, and a plurality of microlenses disposed on the third color filter. Each of the second pattern portions is covered by any one of the first to third color filters.

### BRIEF DESCRIPTION OF THE DRAWINGS

FIG. 1 schematically illustrates an image sensor according to an embodiment of the present inventive concept.

FIG. 2 is a cross-sectional view of an image sensor according to an embodiment of the present inventive concept.

FIG. 3 is a partially enlarged cross-sectional view of an image sensor according to an embodiment of the present inventive concept.

FIGS. 4A and 4B are plan views of some components of an image sensor according to an embodiment of the present inventive concept.

FIGS. 5 and 6 are cross-sectional views of an image sensor according to an embodiment of the present inventive concept.

FIGS. 7 to 10 are partial enlarged cross-sectional views of various modified examples of an image sensor according to an embodiment of the present inventive concept.

FIGS. 11A to 11E are partial enlarged cross-sectional views of various modified examples of an image sensor according to an embodiment of the present inventive concept.

FIG. 12A schematically illustrates another modified example of an image sensor according to an embodiment of the present inventive concept.

FIG. 12B schematically illustrates another modified example of an image sensor according to an embodiment of the present inventive concept.

FIGS. 13, 14, and 15A to 15C are cross-sectional views that illustrate a method of forming an image sensor according to an embodiment of the present inventive concept.

### DETAILED DESCRIPTION

Hereinafter, exemplary embodiments of the present inventive concept will be described with reference to the accompanying drawings.

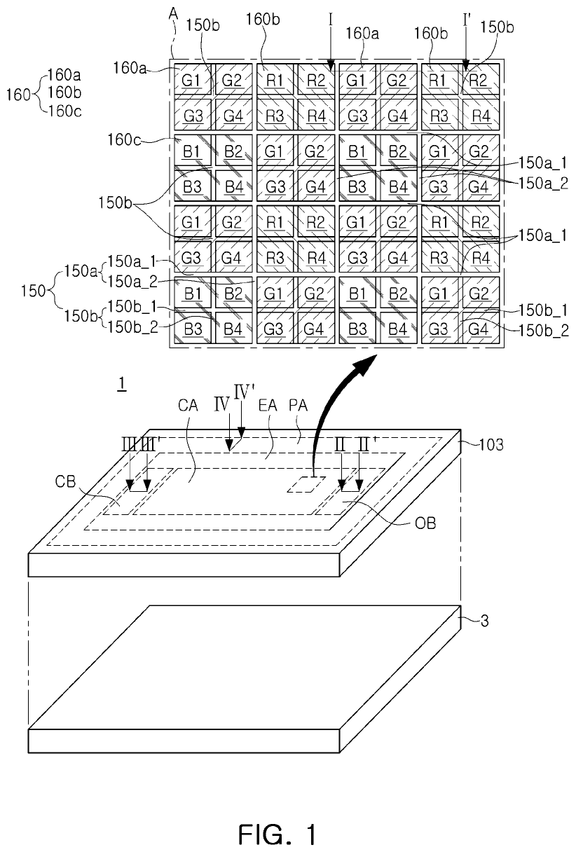

First, an example of an image sensor according to an embodiment of the present inventive concept will be described with reference to FIG. 1. FIG. 1 is an exploded perspective view that illustrates an image sensor according to an embodiment of the present inventive concept, and a partially enlarged portion that illustrates ‘portion A’ in FIG. 1 represents a planar shape in which a portion of the image sensor illustrated in the exploded perspective view is enlarged.

Referring to FIG. 1, an image sensor 1 according to an embodiment includes a first chip structure 3 and a second chip structure 103 disposed on the first chip structure 3. The first chip structure 3 can be a logic chip, and the second chip structure 103 can be an image sensor chip that includes a plurality of pixel regions G1 to G4, R1 to R4, and B1 to B4. In another embodiment, the first chip structure 3 is a stacked chip structure that includes a logic chip and a memory chip.

In an embodiment, the second chip structure 103 of the image sensor 1 includes a first region CA, a second region EA, and a third region PA.

In an embodiment, the third region PA is disposed on at least one side of a central region that includes the first region CA and the second region EA. For example, the third region PA is disposed on both sides of a central region that includes the first region CA and the second region EA, or can be disposed to surround the central region. The second region EA is disposed on at least one side of the first region CA. For example, the second region EA may be disposed on either side of the first region CA, may be disposed on both sides of the first region CA, or may surround the first region CA.

In an embodiment, the first region CA includes an active pixel sensor array region, and the second region EA includes an optical black region OB and a chip-connection region CB. The third region PA includes a pad region in which input/output pads are disposed. The third region PA may be referred to as a pad region.

In an embodiment, the first region CA is an active pixel sensor array region onto which light is incident, and the optical black region OB of the second region EA is a region onto which no light is incident, and the chip-connection region CB of the second region EA electrically connects an interconnection structure of the first chip structure 3 and an interconnection structure of the second chip structure 103. In embodiments, the optical black region OB and the chip-connection region CB may be arranged in various patterns.

In an embodiment, the second chip structure 103 includes a plurality of color filters 160. The color filters 160 include first color filters 160a of a first color, second color filters 160b of a second color, different from the first color, and third color filters 160c of a third color, different from the first and second colors. For example, the first color may be green, the second color may be red, and the third color may be blue.

In an embodiment, the first region CA, which is an active pixel sensor array region, includes a plurality of pixel regions G1 to G4, R1 to R4, and B1 to B4. The plurality of pixel regions G1 to G4, R1 to R4, and B1 to B4 have a planar shape indicated by portion ‘A’ in FIG. 1. A first pixel group (G1 to G4) that includes a G1 pixel region, a G2 pixel region, a G3 pixel region, and a G4 pixel region, adjacent to each other, overlaps one of the first color filters 160a, a second pixel group (R1 to R4) that includes a R1 pixel region, a R2 pixel region, a R3 pixel region, and a R4 pixel region, adjacent to each other, overlaps one of the second color filters 160b, and a third pixel group (B1 to B4) that includes a B1 pixel region, a B2 pixel region, a B3 pixel region, and a B4 pixel region, adjacent to each other, overlaps one of the third color filters 160c.

In an embodiment, when ‘portion A’ in FIG. 1 is viewed in a plan view, the second chip structure 103 further includes a grid pattern structure 150 disposed between each of the pixel regions G1 to G4, R1 to R4, and B1 to B4. The grid pattern structure 150 includes a first pattern portion 150a and second pattern portions 150b. The second pattern portions 150b extend from the first pattern portion 150a.

In an embodiment, when viewed in a plan view, the first pattern portion 150a includes first horizontal straight portions 150a_1 parallel to each other and first vertical straight portions 150a_2 parallel to each other. The first vertical straight portions 150a_2 are perpendicular to the first horizontal straight portions 150a_1. The first pattern portion 150a has a grid shape in which the first horizontal straight portions 150a_1 and the first vertical straight portions 150a_2 vertically intersect.

In an embodiment, the first pattern portion 150a is disposed between color filters of different colors of the first to third color filters 160a, 160b, and 160c. Therefore, each of the first horizontal straight portions 150a_1 and the first vertical straight portions 150a_2 are disposed between color filters of different colors of the first to third color filters 160a, 160b, and 160c.

In an embodiment, when viewed in a plan view, each of the second pattern portions 150b includes a second horizontal straight portion 150b_1 and a second vertical straight portion 150b_2 perpendicular to the second horizontal straight portion 150b_1. The second horizontal straight portion 150b_1 is parallel to the first horizontal straight portions 150a_1 and spaced apart from the first horizontal straight portions 150a_1, and extends from a side surface of an adjacent first vertical straight portion 150a_2. The second vertical straight portion 150b_2 is parallel to the first vertical straight portions 150a_2 and spaced apart from the first vertical straight portions 150a_2, and extends from a side surface of an adjacent first horizontal straight portion 150a_1.

In an embodiment, when viewed in a plan view, each of the second pattern portions 150b overlaps a color filter of one color of the first to third color filters 160a, 160b, and 160c.

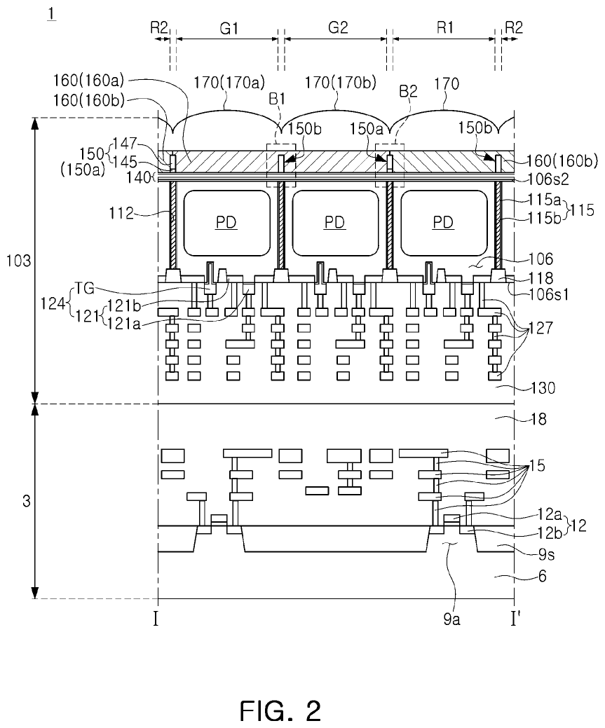

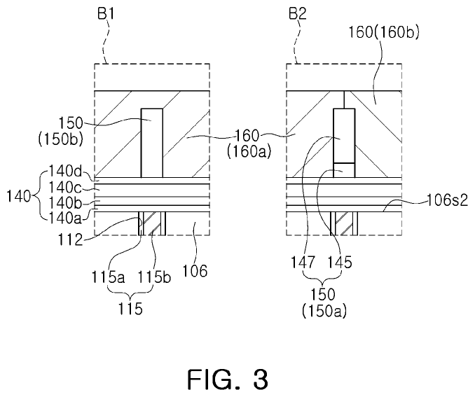

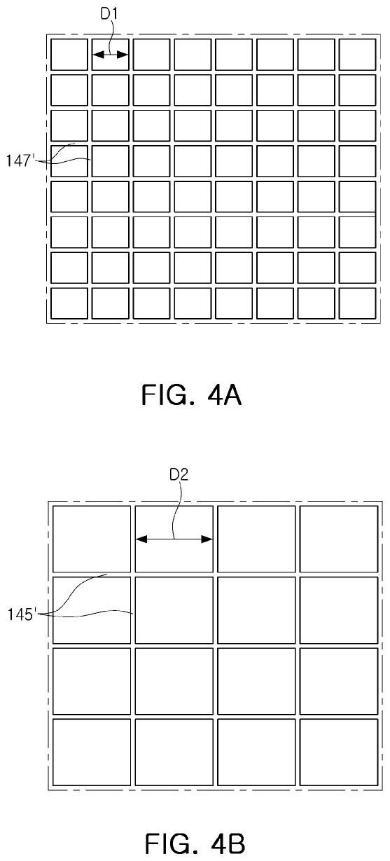

Next, an example of the image sensor 1 described with reference to FIG. 1 will be described with reference to FIGS. 2, 3, 4A, and 4B. FIG. 2 is a cross-sectional view taken along line I-I′ in FIG. 1, and FIG. 3 is a partially enlarged view that illustrates “portion B1” and “portion B2” of FIG. 2, respectively. FIG. 4A is a plan view that illustrates a planar shape of some components of the image sensor, such as a second material pattern 147 in the enlarged portion ‘A’ in FIG. 1, and FIG. 4B is a plan view that illustrates a planar shape of some components of the image sensor, such as a first material pattern 145 in the enlarged portion ‘A’ in FIG. 1.

Referring to FIGS. 2, 3, 4A and 4B, together with FIG. 1, in an embodiment, the first chip structure 3 of the image sensor 1 includes a first substrate 6, a device isolation layer 9s disposed on the first substrate 6 and that defines an active region 9a, a first circuit device 12 and a first interconnection structure 15 disposed on the first substrate 6, and a first insulating layer 18 disposed on the first substrate 6 and that covers the first circuit device 12 and the first interconnection structure 15. The first substrate 6 is a semiconductor substrate. For example, the first substrate 6 is formed of a semiconductor material, such as a single crystal silicon substrate. The first circuit device 12 includes a transistor that includes a gate 12a and a source/drain 12b.

In an embodiment, the pixel regions G1 to G4, R1 to R4, and B1 to B4 of the second chip structure 103 of the image sensor 1 include photoelectric conversion devices PD. For example, each of the pixel regions G1 to G4, R1 to R4, and B1 to B4 includes a photoelectric conversion device PD. The photoelectric conversion devices PD generate and accumulate electric charges that correspond to incident light. For example, the photoelectric conversion devices PD may any one of a photo diode, a photo transistor, a photo gate, a pinned photo diode (PPD), or a combination thereof.

In an embodiment, the second chip structure 103 is formed on a second substrate 106 that includes a first surface 106s1 and a second surface 106s2 that are opposite to each other, a device isolation layer 118 disposed on the first surface 106s1 of the second substrate 106 and that defines an active region, a second circuit device 124 and a second interconnection structure 127 disposed between the first surface 106s1 of the second substrate 106 and the first chip structure 3, and a second insulating layer 130 disposed between the first surface 106s1 of the second substrate 106 and the first chip structure 3 and that covers the second circuit device 124 and the second interconnection structure 127. The first surface 106s1 of the second substrate 106 faces the first chip structure 3.

In an embodiment, the first photoelectric conversion devices PD are formed in the second substrate 106, and are spaced apart from each other. The second substrate 106 is a semiconductor substrate. For example, the second substrate 106 is formed of a semiconductor material, such as a single crystal silicon substrate.

In an embodiment, the second chip structure 103 further includes a separation structure 115. The separation structure 115 surrounds each of the photoelectric conversion devices PD. The separation structure 115 is disposed in a through-opening 112 that penetrates through the second substrate 106. The separation structure 115 penetrates through the second substrate 106. The through-opening 112 is connected to the device isolation layer 118. Therefore, the separation structure 115 is connected to the device isolation layer 118. The device isolation layer 118 is formed of an insulating material such as silicon oxide, etc. The separation structure 115 includes a separation pattern 115b and a separation insulating layer 115a that covers side surfaces of the separation pattern 115b. For example, the separation insulating layer 115a includes silicon oxide, and the separation pattern 115b includes polysilicon.

In an embodiment, the second circuit device 124 includes a transfer gate TG and active devices 121. The active devices 121 are transistors that include a gate 121a and a source/drain 121b. The transfer gate TG transfers electric charges from an adjacent photoelectric conversion device PD to an adjacent floating diffusion region, and the active devices 121 are at least one of a source follower transformer, a reset transistor, or a select transistor. The transfer gate TG is a vertical transfer gate that includes a portion that extends into the second substrate 106 from the first surface 106s1 of the second substrate 106.

In an embodiment, the second interconnection structure 127 includes multilayer interconnection lines located at different levels, and vias that electrically connect the multilayer interconnection lines and electrically connect the multilayer interconnection lines to the second circuit device 124.

In an embodiment, the first insulating layer 18 and the second insulating layer 130 are bonded together and in contact with each other. Each of the first and second insulating layers 18 and 130 has a multilayer structure that includes different types of insulating layers. For example, the second insulating layer 130 is a multilayer structure that includes at least two types of silicon oxide layers, a low-k dielectric layer, and a silicon nitride layer.

In an embodiment, the second chip structure 103 further includes an insulating structure 140 disposed on the second surface 106s2 of the second substrate 106. The insulating structure 140 covers the separation structure 115.

As illustrated in FIG. 3, in an embodiment, the insulating structure 140 includes a plurality of sequentially stacked layers. The insulating structure 140 includes an antireflection layer that can adjust a refractive index such that incident light propagates to the photoelectric conversion devices PD with high transmittance. For example, the insulating structure 140 includes at least two or more of an aluminum oxide layer, a hafnium oxide layer, a silicon oxynitride layer, a silicon oxide layer, or a silicon nitride layer. For example, the insulating structure 140 includes a first layer 140a, a second layer 140b, a third layer 140c, and a fourth layer 140d that are sequentially stacked. The first layer 140a may be an aluminum oxide layer, each of the second and fourth layers 140b and 140d may be a hafnium oxide layer, and the third layer 140c may be a silicon oxide layer.

In an embodiment, a thickness of the first layer 140a is substantially the same as a thickness of the fourth layer 140d.

In an embodiment, a thickness of the second layer 140b is greater than a thickness of each of the first and fourth layers 140a and 140d. For example, a thickness of the second layer 140b ranges from about 5 times to about 7 times a thickness of the first layer 140a.

In an embodiment, a thickness of the third layer 140c is greater than a thickness of the second layer 140b. A thickness of the third layer 140c ranges from about 6 times to about 8 times a thickness of the first layer 140a.

As described in FIG. 1, in an embodiment, the second chip structure 103 includes the grid pattern structure 150 that includes the first pattern portion 150a and the second pattern portions 150b. The grid pattern structure 150 is disposed on the insulating structure 140.

In an embodiment, the first pattern portion 150a includes a first material pattern 145 and a second material pattern 147 disposed on the first material pattern 145. The first material pattern 145 of the first pattern portion 150a and the second pattern portions 150b are in contact with the insulating structure 140. A thickness of the second material pattern 147 is greater than a thickness of the first material pattern 145.

In an embodiment, the first material pattern 145 includes a first material, and the second material pattern 147 and the second pattern portions 150b include a second material that differs from the first material.

In an embodiment, the first material of the first material pattern 145 includes a conductive material. For example, the first material pattern 145 is formed of a conductive material that includes at least one of a metal or a metal nitride. For example, the first material pattern 145 includes at least one of Ti, Ta, TiN, TaN, or W.

In an embodiment, the second material of the second material pattern 147 and the second pattern portions 150b includes an insulating material. The second material of the second material pattern 147 and the second pattern portions 150b is a low refractive index (LRI) material. For example, the second material pattern 147 and the second pattern portions 150b each have a refractive index in the range from about 1.1 to about 1.8. The second material pattern 147 and the second pattern portions 150b each include an oxide or a nitride that includes Si, Al, or a combination thereof. For example, the second material pattern 147 and the second pattern portions 150b each includes a silicon oxide that has a porous structure or silica nanoparticles that have a network structure.

In an embodiment, the second pattern portions 150b is formed of the same second material as the second material pattern 147 of the first pattern portion 150a. Therefore, the first pattern portion 150a and the second pattern portions 150b can be described as including the second material pattern 147 commonly formed of the second material. None of the second pattern portions 150b include the first material in a region in which the second horizontal straight portion 150b_1 and the second vertical straight portion 150b_2 intersect. The second pattern portions 150b do not include the first material.

In FIG. 4A, in an embodiment, a portion indicated by reference numeral 147′ indicates a layer of the second material of the second material pattern 147 and the second pattern portions 150b. Therefore, as illustrated in FIG. 4A, a second material layer 147′ is disposed in a grid shape in which intersections of vertical portions and horizontal portions are separated by a first interval D1. In FIG. 4B, a portion indicated by reference numeral 145′ indicates a layer of the first material of the first material pattern 145. Therefore, the first material layer 145′ is disposed in a grid shape in which intersections of vertical portions and horizontal portions are separated by a second interval D2 that is greater than the first interval D1, as illustrated in FIG. 4B.

As described with reference to FIG. 1, the second chip structure 103 includes the color filters 160 that include the first to third color filters 160a, 160b, and 160c. The color filters 160 are disposed on the insulating structure 140. The color filters 160 pass light of a specific wavelength to reach the photoelectric conversion devices PD. For example, the color filters 160 are formed of a material obtained by mixing a resin with a pigment that includes a metal or a metal oxide. The thickness of each of the color filters 160 is greater than the thickness of the grid pattern structure 150. The color filters 160 are disposed on the insulating structure 140 and cover the grid pattern structure 150. The color filters 160 cover side and upper surfaces of the grid pattern structure 150.

In an embodiment, in the grid pattern structure 150, the first pattern portion 150a are disposed between filters of different colors of the first to third color filters 160a, 160b, and 160c.

In an embodiment, the first pattern portion 150a may include side surfaces opposite to each other, and the side surfaces of the first pattern portion 150a are in contact with or adjacent to filters of different colors. For example, a portion of the first pattern portion 150a includes a first side surface that contacts the first color filter 160a and a second side surface that contacts the second color filter 160b. In an embodiment, an upper surface of the first pattern portion 150a is in contact with different color filters, such as the first color filter 160a and the second color filter 160b.

In an embodiment, each of the second pattern portions 150b includes side surfaces opposite to each other, and the side surfaces of a second pattern 150b are in contact with or adjacent to filters of the same color. For example, a second pattern portion 150b includes side surfaces that contact the first color filter 160a. In an embodiment, a second pattern portion includes side surfaces that contact the first color filter 160a and an upper surface that contacts the first color filter 160a. One of the color filters 160 covers the upper surface and the side surfaces of one of the second pattern portions 150b.

In an embodiment, the second chip structure 103 further includes microlenses 170 disposed on the color filters 160. The microlenses 170 are disposed as a plurality of microlenses on the first color filter 160a, as a plurality of microlenses on the second color filter 160b, and as a plurality of microlenses on the third color filter 160c. Each of the microlenses 170 overlaps a corresponding photoelectric conversion device PD. Each of the microlenses 170 has a convex shape in a direction away from the first chip structure 3. The microlenses 170 condense incident light into the photoelectric conversion devices PD. The microlenses 170 may be formed of a transparent photoresist material or a transparent thermosetting resin material. For example, the microlenses 170 may be formed of a TMR series resin (manufactured by Tokyo Ohka Kogo, Co.) or an MFR series resin (manufactured by Japan Synthetic Rubber Corporation), but embodiments are not limited to these materials.

In an embodiment, each of the microlenses 170 is convex in a direction away from the first chip structure 3, such as a direction away from the second substrate 106. The centers of each of the microlenses 170 do not overlap the second pattern portions 150b. For example, in the cross-sectional structure of FIG. 2, a first microlens 170a and a second microlens 170b that are adjacent to each other in a horizontal direction are disposed on one of the first color filters 160a. The second pattern portion 150b does not overlap a center of the first microlens 170a or a center of the second microlens 170b, but overlaps a boundary region between the first microlens 170a and the second microlens 170b. In this case, the center of each of the microlenses 170 is the most convex portion of each of the microlenses 170. One of the second pattern portions 150b includes a portion that overlaps a boundary between the adjacent first microlens 170a and second microlens 170b.

According to above-described embodiments, any one of the color filters 160, such as the first color filter 160a, overlaps a plurality of photoelectric conversion devices PD in the plurality of pixel regions G1 to G4, to improve sensitivity of the same color in the image sensor 1, such as the first color of the first color filter 160a. Likewise, sensitivity of the second and third colors may also be improved for the same reason as the first color.

According to above-described embodiments, in the grid pattern structure 150, the first pattern portion 150a disposed between color filters of different colors includes the first material pattern 145 formed of a conductive material that serve as a charge path that removes charge, and the second pattern portions 150b, which have side surfaces and the upper surface covered by color filters of the same color, do not include a conductive material, which reduces sensitivity in pixel regions that overlap color filters of the same color, to further improve sensitivity of the same color of the image sensor 1, and reduce optical cross-talk.

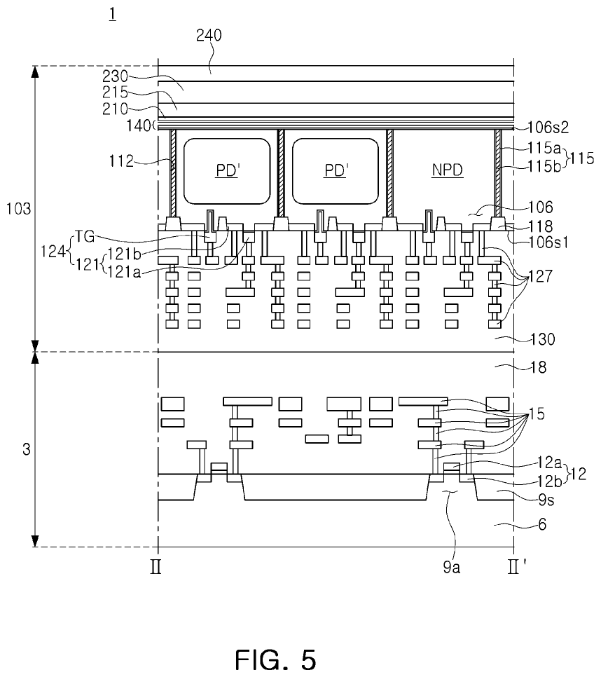

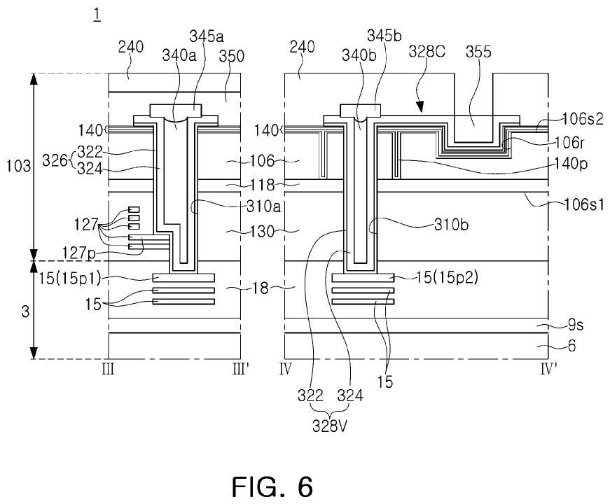

Next, in an embodiment, referring to FIGS. 5 and 6, a cross-sectional structure of the image sensor 1 that includes the optical black region OB, a cross-sectional structure of the image sensor 1 that includes the chip-connection region CB, and a cross-sectional structure of the image sensor 1 that includes the pad region PA, described in FIG. 1, will be described. FIG. 5 is a cross-sectional view taken along line II-IF of FIG. 1, and FIG. 6 is a cross-sectional view taken along lines III-III′ and IV-IV′ of FIG. 1, The cross-sectional structure of FIG. 5 that illustrates FIG. 1 along line II-IF is a cross-section of the image sensor 1 that includes the optical black region OB shown in FIG. 1. The cross-sectional structure of FIG. 6 that illustrates FIG. 1 along line III-III′ is a cross-section of the image sensor 1 that includes the chip-connection region CB shown in FIG. 1, and the cross-sectional structure of FIG. 6 that illustrates FIG. 1 along line IV-IV′ is a cross-section of the image sensor 1 that includes the pad region PA shown in FIG. 1. Hereinafter, in describing the cross-sectional structures of the image sensor 1 with reference to each of FIGS. 5 and 6, descriptions of components that described with reference to FIGS. 1 to 4B will be omitted.

Referring to FIG. 5, in an embodiment, together with FIGS. 1 to 4B, in the optical black region OB of the second chip structure 103, a region in which a photoelectric conversion device PD′ is formed in the same manner as the photoelectric conversion devices PD described above is defined as a first reference region, and a region NPD in which no photoelectric conversion device PD is formed is defined as a second reference region.

In an embodiment, the first reference region PD′ and the second reference region NPD are disposed in the second substrate 106, and are separated by the separation structure 115. For example, the separation structure 115 surrounds side surfaces of the first reference region PD′ and side surfaces of the second reference region NPD.

In an embodiment, the second reference region NPD is a comparison region that does not include the photoelectric conversion devices PD or the photodiodes of the photoelectric conversion devices PD.

In an embodiment, in the optical black region OB of the second region EA of the image sensor 1, the second chip structure 103 includes the insulating structure 140, as described above, disposed on the second surface 106s2 of the second substrate 106.

In an embodiment, in the optical black region OB of the second region EA of the image sensor 1, the second chip structure 103 further includes light blocking conductive layers 210 and 215, a light blocking color filter layer 230, and an upper capping layer 240 that are sequentially stacked on the insulating structure 140.

In an embodiment, the light blocking conductive layers 210 and 215 and the light blocking color filter layer 230 form a light blocking pattern that blocks light. The light blocking pattern blocks light from entering the first reference region PD′ and the second reference region NPD. The light blocking conductive layers 210 and 215 include a metal nitride layer, such as TiN or WN, etc., and a metal layer, such as Ti, W, Cu, Al, Cu, or Ag, etc., that are sequentially stacked. The light blocking color filter layer 230 includes a blue color filter. The upper capping layer 240 includes the same material as the microlenses 170.

In an embodiment, the optical black region OB removes noise caused by a dark current. For example, when light is blocked by the light blocking conductive layers 210 and 215 and the light blocking color filter layer 230, the first reference region PD′, which includes a photodiode, is used as a reference pixel to remove noise by a photodiode. In addition, when light is blocked by the light blocking conductive layers 210 and 215 and the light blocking color filter layer 230, the second reference region NPD, which does not include a photodiode, is used to check process noise for noise removal by components other than a photodiode.

Referring to FIG. 6, together with FIGS. 1 to 5, in an embodiment, the image sensor 1 includes a first via hole 310a in the chip-connection region CB of the second region EA that penetrates through at least a portion of the second chip structure 103 and extends into the first chip structure 3, and a second via hole 310b in the third region PA that penetrates through at least a portion of the second chip structure 103 and extends into the first chip structure 3.

In an embodiment, the first via hole 310a sequentially penetrates through the insulating structure 140 and the second substrate 106, extends downward to sequentially penetrate through the device isolation layer 118 and the second insulating layer 130, and extends into the first insulating layer 18. The second via hole 310b sequentially penetrates through the insulating structure 140 and the second substrate 106, extends downward to sequentially penetrate through the device isolation layer 118 and the second insulating layer 130, and extends into the first insulating layer 18.

In an embodiment, the first via hole 310a exposes a first pad 15p1 of the first interconnection structure 15 and a pad portion 127p of the second interconnection structure 127, and the second via hole 310b exposes a second pad 15p2 of the first interconnection structure 15 and is spaced apart from the second interconnection structure 127.

In an embodiment, the image sensor 1 includes a connection conductive layer 326 in the first via hole 310a and an input/output conductive layer 328V in the second via hole 310b. The connection conductive layer 326 electrically connects the first and second interconnection structures 15 and 127.

In an embodiment, the connection conductive layer 326 and the input/output conductive layer 328V each include a first conductive layer 322 and a second conductive layer 324. The first conductive layer 322 is a barrier material, such as TiN, etc., and the second conductive layer 324 is a metal, such as W, Cu, or Al, etc.

In an embodiment, the image sensor 1 further includes gap-fill insulating layers 340a and 340b disposed on the connection conductive layer 326 and the input/output conductive layer 328V and respectively filling the first and second via holes 310a and 310b, respectively, and that have concave-shaped upper surfaces, and buffer insulating layers 345a and 345b that respectively cover the gap-fill insulating layers 340a and 340b and that have upper surfaces located higher than an upper surface of the insulating structure 140. The buffer insulating layers 345a and 345b each include a cured photoresist material.

In an embodiment, the image sensor 1 further includes a light blocking color filter layer 350 disposed in the chip-connection region CB of the second region EA and that covers the buffer insulating layer 345a and the insulating structure 140. The light blocking color filter layer 350 in the chip-connection region CB of the second region EA extends from the light blocking color filter layer 230 in the optical black region OB of the second region EA. The light blocking color filter layers 230 and 350 may be formed of the same material, and may be, for example, a blue color filter.

In an embodiment, the image sensor 1 further includes an input/output pad 355 in the third region PA. The input/output pad 355 is disposed on an extension portion 328C that extends from the input/output conductive layer 328V. At least a portion of the input/output pad 355 is buried in the second substrate 106. For example, the input/output pad 355 has an upper surface located higher than the second surface 106s2 of the second substrate 106, and a lower surface located lower than the second surface 106s2 of the second substrate 106. The insulating structure 140 is disposed on the second surface 106s2 of the second substrate 106, and the extension portion 328C of the input/output conductive layer 328V is disposed on the insulating structure 140. The upper capping layer 240 in the optical black region OB of the second region EA extends into the chip-connection region CB of the second region EA and the third region PA. The upper capping layer 240 covers the chip-connection region CB of the second region EA, exposes the input/output pad 355 in the third region PA, and covers a remaining portion of the third region PA.

In an embodiment, the image sensor 1 further includes a separation pattern 140p that penetrates through the second substrate 106 in the third region PA. For example, the separation pattern 140p extends into the second substrate 106 from at least a portion of the insulating structure 140.

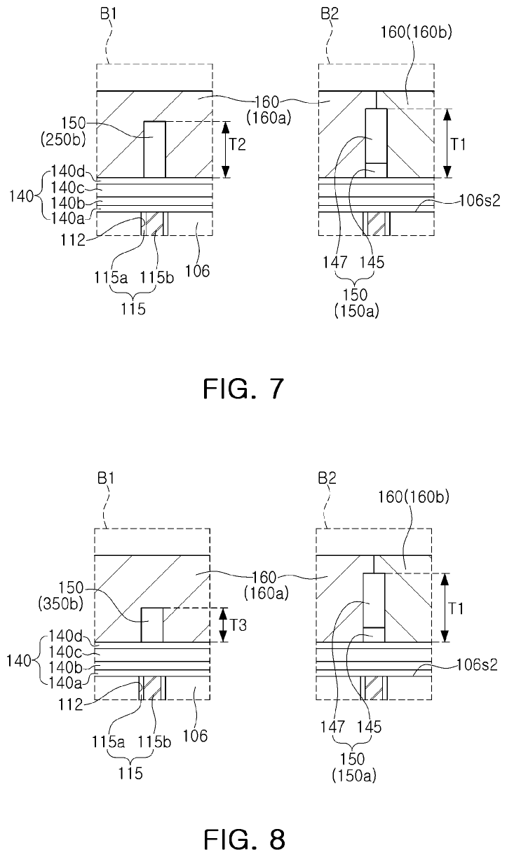

Referring to FIGS. 1 to 4B again, in an embodiment, each of the second pattern portions 150b has a width and a height that are substantially the same as a width and a height of the first pattern portion 150a, respectively. However, embodiments of the technical concept of the present inventive concept are not limited thereto. For example, in other embodiments, at least one of the second pattern portions 150b is modified to have a width or a height that differs from a width or a height of the first pattern portion 150a. Hereinafter, a modified example of the second pattern portion will be described with reference to FIGS. 7 to 10. FIGS. 7 to 10 illustrate modified examples of the partially enlarged regions “B1” and “B2” of FIG. 3. Hereinafter, with reference to each of FIGS. 7 to 10, a description will be given that focuses on a modified example of the second pattern portion 150b of the components of FIG. 3.

In a modified example according to an embodiment, referring to FIG. 7, in the grid pattern structure 150, the first pattern portion 150a has a first height T1, and a second pattern portion 250b may have a second height T2 that is less than the first height T1 and greater than half the first height T1.

In a modified example according to an embodiment, referring to FIG. 8, in the grid pattern structure 150, the first pattern portion 150a may have a first height T1, and a second pattern portion 350b may have a third height T3 that is equal to or less than half the first height T1.

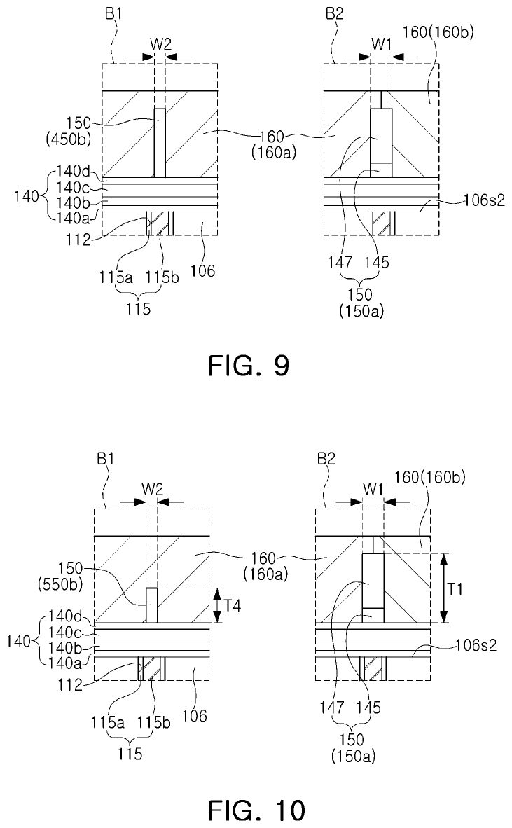

In a modified example according to an embodiment, referring to FIG. 9, in the grid pattern structure 150, the first pattern portion 150a has a first width W1, and a second pattern portion 450b has a second width W2 that is less than the first width W1.

In a modified example according to an embodiment, referring to FIG. 10, in the grid pattern structure 150, the first pattern portion 150a has a first width W1 and a first height T1, and a second pattern portion 550b has a second width W2 that is less than the first width W1, and a fourth height T4 that is less than the first height T1.

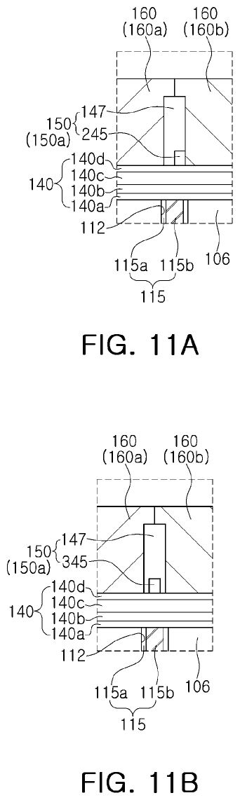

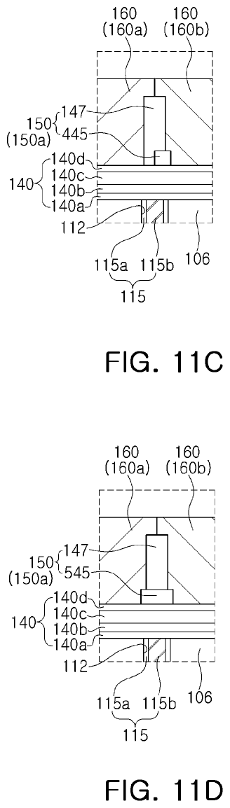

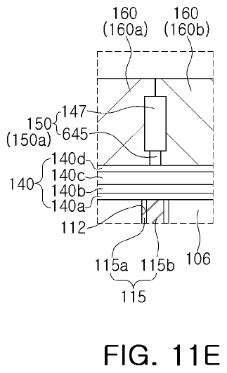

Referring to FIG. 3 again, in an embodiment, side surfaces of the first material pattern 145 and side surfaces of the second material pattern 147 of the first pattern portion 150a are vertically aligned, and a width of the first material pattern 145 and a width of the second material pattern 147 are substantially the same. Alternatively, in another embodiment, side surfaces of the first material pattern 145 and side surfaces of the second material pattern 147 of the first pattern portion 150a are not vertically aligned, or a width of the first material pattern 145 and a width of the second material pattern 147 are not the same. Hereinafter, modified examples of the first pattern portion 150a of the grid pattern structure 150 will be described with reference to FIGS. 11A to 11E, respectively. FIGS. 11A to 11E illustrate modified examples of the partially enlarged region “B2” in FIG. 3.

In a modified example according to an embodiment, referring to FIG. 11A, in a first pattern portion 150a of the grid pattern structure 150, a width of a first material pattern 245 is less than a width of the second material pattern 147. One of the side surfaces of the first material pattern 245 is in contact with the second material pattern 147, and the other side surface thereof is in contact with a color filter, such as the second color filter 160b. In the first pattern portion 150a of the grid pattern structure 150, the second material pattern 147 covers one of the side surfaces of the first material pattern 245 and contacts the insulating structure 140.

In a modified example according to an embodiment, referring to FIG. 11B, in a first pattern portion 150a of the grid pattern structure 150, a width of a first material pattern 345 is less than a width of the second material pattern 147. In addition, side surfaces of the first material pattern 345 are in contact with the second material pattern 147. The second material pattern 147 is in contact with the insulating structure 140 while covering the side surfaces of the first material pattern 345.

In a modified example according to an embodiment, referring to FIG. 11C, in a first pattern portion 150a of the grid pattern structure 150, a portion of an upper surface of a first material pattern 445 is in contact with a color filter, such as the second color filter 160b. One of the side surfaces of the first material pattern 445 is in contact with the second material pattern 147, and the other side surface thereof is in contact with a color filter, such as the second color 160b. The second material pattern 147 is in contact with the insulating structure 140.

In a modified example according to an embodiment, referring to FIG. 11D, in a first pattern portion 150a of the grid pattern structure 150, a width of a first material pattern 545 is greater than a width of the second material pattern 147. In addition, side surfaces of the second material pattern 147 overlap an upper surface of the first material pattern 645. The color filters 160 located on side surfaces of the first pattern portion 150a are in contact with a portion of the upper surface of the first material pattern 645.

In a modified example according to an embodiment, referring to FIG. 11E, in a first pattern portion 150a of the grid pattern structure 150, a width of a first material pattern 645 is less than a width of the second material pattern 147. In addition, side surfaces of the first material pattern 645 overlap a lower surface of the second material pattern 147. The color filters 160 located on side surfaces of the first pattern portion 150a are in contact with a portion of the lower surface of the second material pattern 147.

Referring to FIG. 1 again, in embodiment, when viewed in a plan view, in the grid pattern structure 150, the first pattern portion 150a includes the first horizontal straight portions 150a_1 parallel to each other, and the first vertical straight portions 150a_2 that are perpendicular to the first horizontal straight portions 150a_1 and parallel to each other, and the second pattern portions 150b include the second horizontal straight portions 150b_1 parallel to the first horizontal straight portions 150a_1, and the second vertical straight portion 150b_2 parallel to the first vertical straight portions 150a_2.

In another embodiment, between a pair of first horizontal straight portions 150a_1 parallel and adjacent to each other, the second horizontal straight portions 150b_1 are provided as a plurality of second horizontal straight portions parallel to each other, and between a pair of first vertical straight portions 150a_2 parallel and adjacent to each other, the second vertical straight portions 150b_2 are provided as a plurality of second vertical straight portions parallel to each other.

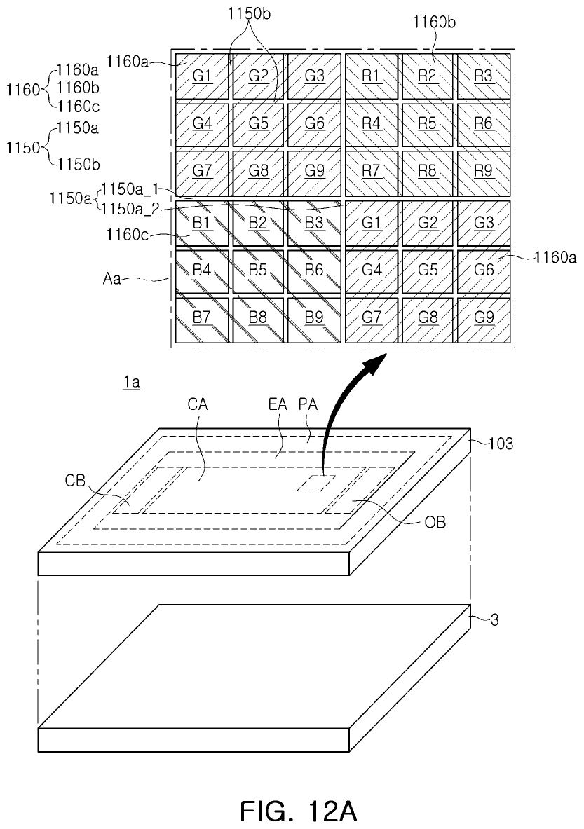

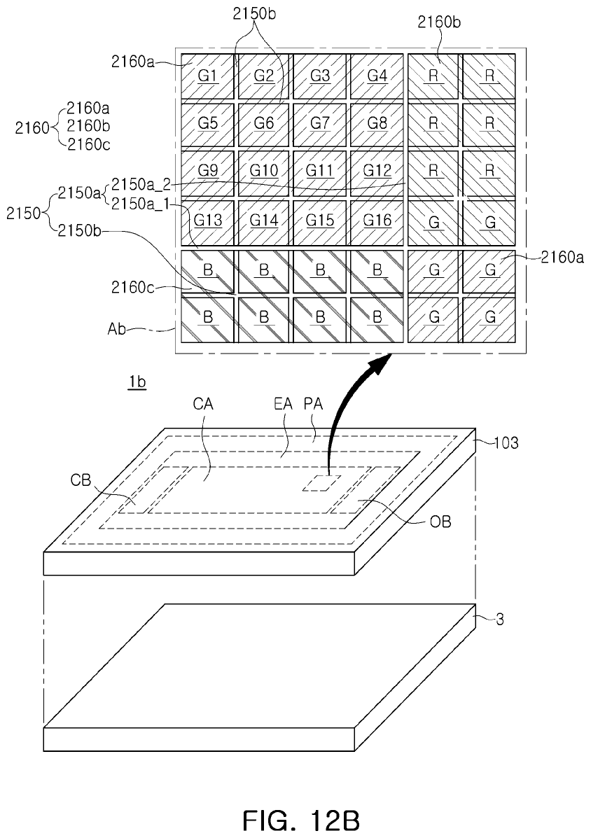

Next, modified examples of the grid pattern structure 150 and the color filters 160 described above will be described with reference to FIGS. 12A and 12B, respectively.

In an embodiment, referring to FIG. 12A, color filters 1160 include first color filters 1160a of a first color, second color filters 1160b of a second color, and third color filters 1160c of a third color. One of the first color filters 1160a overlaps nine pixel regions indicated by G1 to G9, one of the second color filters 1160b overlaps nine pixel regions indicated by R1 to R9, and one of the third color filters 1160c overlaps nine pixel regions indicated by B1 to B9.

In an embodiment like the grid pattern structure 150 described in FIG. 1, a grid pattern structure 1150 includes a first pattern portion 1150a disposed between color filters of different colors, and a second pattern portions 1150b that overlap color filters of one color. The first pattern portion 1150a includes first horizontal straight portions 1150a_1 that are parallel to each other, and first vertical straight portions 1150a_2 that are perpendicular to the first horizontal straight portions 1150a_1 and parallel to each other, and each of the second pattern portions 1150b includes a plurality of second horizontal straight portions 1150b_1 that are parallel to the first horizontal straight portions 1150a_1, and a plurality of second vertical straight portions 1150b_2 that are parallel to the first vertical straight portions 1150a_2.

In an embodiment between a pair of adjacent and parallel first horizontal straight portions 1150a_1, a plurality of the second horizontal straight portions 1150b_1 of the second pattern portion 1150b are provided, such as two parallel second horizontal straight portions. Between a pair of adjacent and parallel first vertical straight portions 1150a_2, a plurality of the second vertical straight portions 1150b_2 of the second pattern portion 1150b are provided, such as two parallel second vertical straight portions.

In an embodiment, referring to FIG. 12B, color filters 2160 include first color filters 2160a of a first color, second color filters 2160b of a second color, and third color filters 2160c of a third color. Any one of the first to third color filters 2160a, 2160b, and 2160c, such as the first color filters 2160a, overlaps sixteen pixel regions indicated by G1 to G16. Like the grid pattern structure 1150 described in FIG. 12A, a grid pattern structure 2150 includes a first pattern portion 2150a that is disposed between color filters of different colors, and a second pattern portions 2150b that overlaps color filters of one color. The first pattern portion 2150a includes first horizontal straight portions 2150a_1 that are parallel to each other, and first vertical straight portions 2150a_2 that are perpendicular to the first horizontal straight portions 2150a_1 and parallel to each other, and each of the second pattern portions 2150b includes a plurality of second horizontal straight portions 2150b_1 that are parallel to the first horizontal straight portions 2150a_1, and a plurality of second vertical straight portions 2150b_2 that are parallel to the first vertical straight portions 2150a_2.

In an embodiment, between a pair of parallel and adjacent first horizontal straight portions 2150a_1, a plurality of the second horizontal straight portions 2150b_1 of the second pattern portion 2150b are provided, such as three parallel second horizontal straight portions. Between a pair of parallel and adjacent first vertical straight portions 2150a_2, a plurality of the second vertical straight portions 2150b_2 of the second pattern portion 2150b are provided, such as three parallel second vertical straight portions.

In an embodiment, between the pair of parallel and adjacent first horizontal straight portions 2150a_1 and between the pair of parallel and adjacent first vertical straight portions 2150a_2, the number of the second vertical straight portions 2150b_2 and the number of the second horizontal straight portions 2150b_1 in the second pattern portion 2150b are the same.

Although the above-described embodiments have been described in terms of one color filter in FIG. 1, such as the first color filter 160a, overlapping four pixel regions indicated by G1 to G4, any color filter in FIG. 12A, such as the first color filter 1160a, overlaps nine pixel regions indicated by G1 to G9, and any color filter in FIG. 12B, such as the first color filter 2160a, overlaps sixteen pixel regions indicated by G1 to G16. However, embodiments of the technical concept of the present inventive concept are not limited thereto. For example, in other embodiments of the technical concept of the present inventive concept, a color filter can overlap sixteen or more pixel regions.

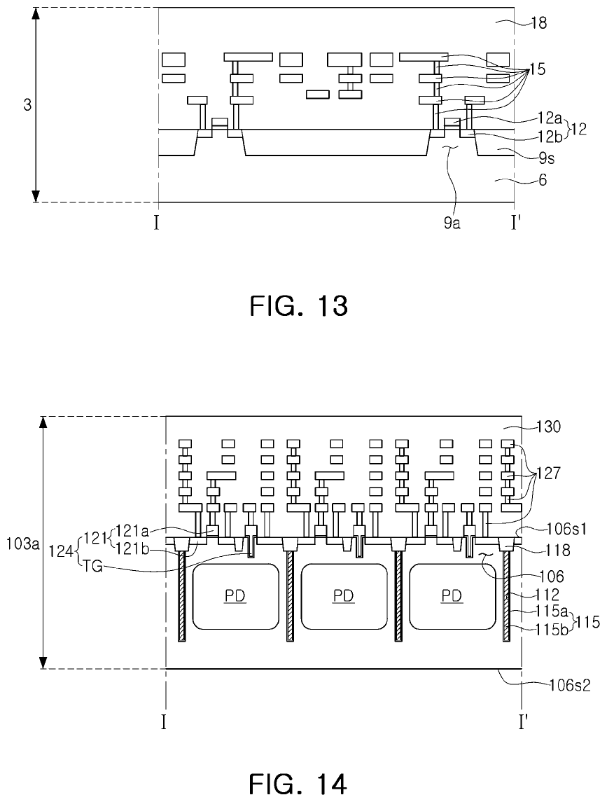

Next, an example of a method of forming an image sensor according to an embodiment of the present inventive concept will be described. FIGS. 13, 14, and 15A to 15C are cross-sectional views of FIG. 1, taken along line I-I′ that illustrate a method of forming an image sensor according to an embodiment of the present inventive concept.

Referring to FIG. 13, in an embodiment, a first chip structure 3 is formed. The formation of the first chip structure 3 includes preparing a first substrate 6, forming a device isolation layer 9s on the first substrate 6 that defines an active region 9a, forming a first circuit device 12 on the first substrate 6, forming a first interconnection structure 15 on the first substrate 6 that is electrically connected to the first circuit device 12, and forming a first insulating layer 18 that covers the first circuit device 12 and the first interconnection structure 15.

Referring to FIG. 14, in an embodiment, a second chip 103a is formed. The formation of the second chip 103a includes preparing a second substrate 106 that has a first surface 106s1 and a second surface 106s2 that are opposite to each other, forming a separation structure 115 and photoelectric conversion devices PD in the second substrate 106, forming a device isolation layer 118 on the first surface 106s1 of the second substrate 106 that defines an active region, forming a second circuit device 124 on the first surface 106s1 of the second substrate 106, forming a second interconnection structure 127 on the first surface 106s1 of the second substrate 106, and forming a second insulating layer 130 that covers the second circuit device 124 and the second interconnection structure 127. However, the order of forming the separation structure 115, the photoelectric conversion devices PD, and the device isolation layer 118 can be changed in other embodiments.

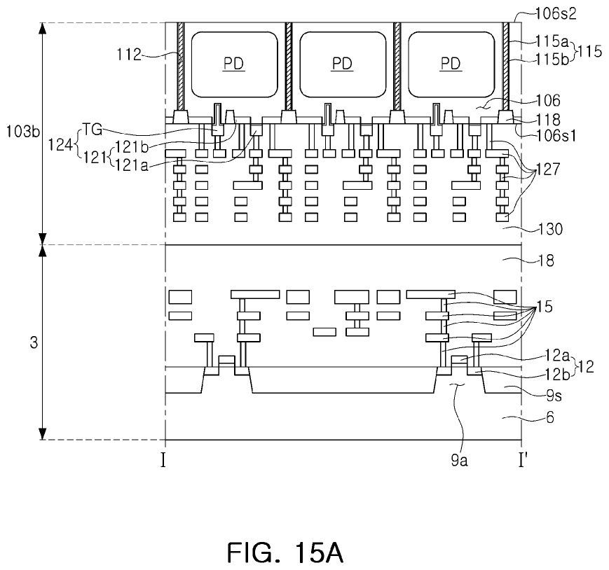

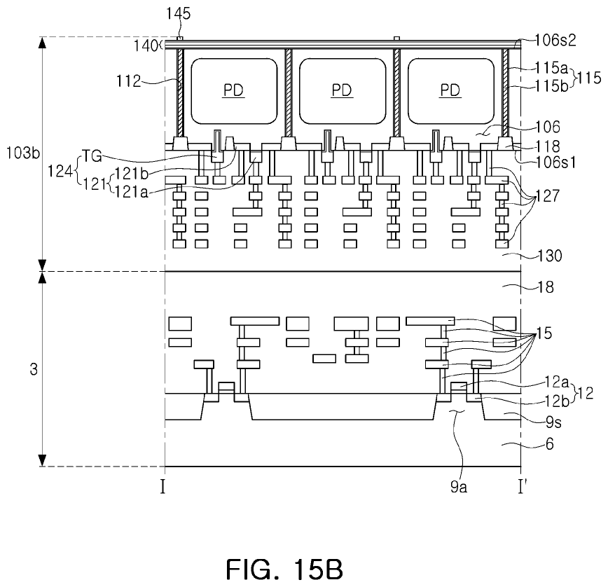

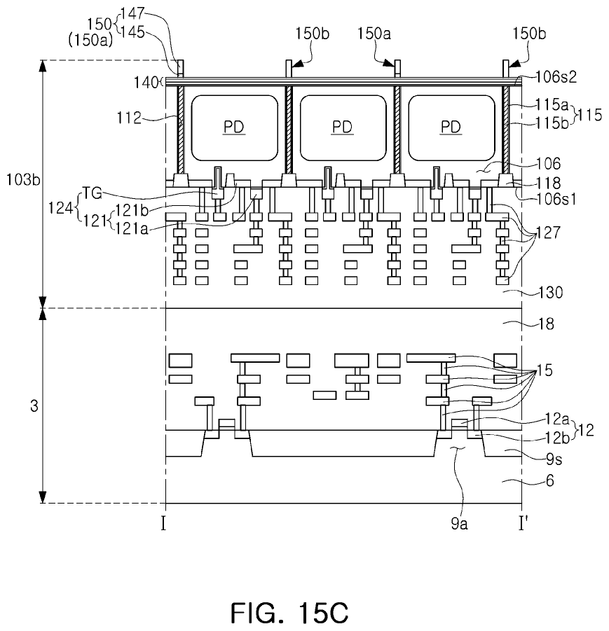

Referring to FIG. 15A, in an embodiment, a wafer bonding process that bonds two wafers is performed that bond the first chip structure 3 and the second chip 103a to each other. The first insulating layer 18 of the first chip structure 3 and the second insulating layer 130 of the second chip 103a are bonded to each other. A grinding process is performed that reduces a thickness of the second substrate 106 of the second chip 103a and exposes the separation structure 115 in the second substrate 106.

In an embodiment, the insulating structure 140 described in FIGS. 2 and 3 is formed on the second surface 106s2 of the reduced thickness second substrate 106. The first material pattern 145 illustrated in FIGS. 2 and 4B is formed on the insulating structure 140. Therefore, a structure 103b that is formed up to the insulating structure 140 and the first material pattern 145 is prepared on the first chip structure 3.

Referring to FIG. 15C, in an embodiment, the second material pattern 147 is formed on the first material pattern 145. Therefore, the grid pattern structure 150, which includes the first pattern portion 150a that includes the first material pattern 145 and the second material pattern 147, and the second pattern portions 150b formed of the same material as the second material pattern 147 are prepared.

Referring again to FIGS. 1 and 2, in an embodiment, the color filters 160 that cover the grid pattern structure 150 are formed on the insulating structure 140, and the microlenses 170 are formed on the color filters 160.

According to embodiments of the present inventive concept, one color filter overlaps a plurality of photoelectric conversion devices in a plurality of pixel regions to improve sensitivity of the color in an image sensor.

According to embodiments of the present inventive concept, a grid pattern structure includes a first pattern portion that includes a conductive material and is disposed between color filters of different colors and a second pattern portion that does not include a conductive material and has side surfaces and an upper surface that are covered by color filters of the same color. An image sensor with this grid pattern structure has increased sensitivity to the same color and reduced optical cross-talk. Therefore, the image sensor has increased resolution.

While exemplary embodiments have been illustrated and described above, it will be apparent to those skilled in the art that modifications and variations could be made without departing from the scope of embodiments of the present inventive concept as defined by the appended claims.

What is claimed is:

1. An image sensor, comprising:
a first chip structure that includes a first substrate; and
a second chip structure disposed on the first chip structure,
wherein the second chip structure includes:
a second substrate that has a first surface that faces the first chip structure and a second surface opposite to the first surface;
photoelectric conversion devices disposed in the second substrate;
an insulating structure disposed on the second surface of the second substrate;
a grid pattern structure disposed on the insulating structure;
color filters disposed on the insulating structure and the grid pattern structure; and
microlenses disposed on the color filters,
wherein the grid pattern structure includes a first pattern portion and second pattern portions,
wherein the first pattern portion includes a first material pattern and a second material pattern disposed on the first material pattern,
wherein the first material pattern is formed of a first material,
the second pattern portions and the second material pattern are formed of a second material that differs from the first material, and
a center of each of the microlenses does not overlap the second pattern portions.

2. The image sensor of claim 1, wherein the second pattern portions are in contact with the insulating structure, and
the first material pattern of the first pattern portion is in contact with the insulating structure.

3. The image sensor of claim 1, wherein the first material of the first material pattern comprises a conductive material, and
the second material of the second material pattern and the second pattern portions comprises an insulating material.

4. The image sensor of claim 1, wherein an intermediate portion of the second pattern portions between opposite side surfaces of each of the second pattern portions does not comprise the first material.

5. The image sensor of claim 1, wherein a thickness of the second material pattern is greater than a thickness of the first material pattern.

6. The image sensor of claim 1, wherein, when viewed in a plan view,
the first pattern portion comprises first horizontal straight portions parallel to each other, and first vertical straight portions that are parallel to each other and perpendicular to the first horizontal straight portions,
each of the second pattern portions comprises a second horizontal straight portion parallel to the first horizontal straight portions, and a second vertical straight portion parallel to the first vertical straight portions, and
the second horizontal straight portion of each of the second pattern portions is perpendicular to the second vertical straight portion.

7. The image sensor of claim 6, wherein a plurality of the second horizontal straight portion and a plurality of the second vertical straight portion are provided between each pair of adjacent first horizontal straight portions and between each pair of adjacent first vertical straight portions, and
wherein the plurality of second horizontal straight portions are perpendicular to the plurality of second vertical straight portions.

8. The image sensor of claim 1, wherein a height of the first pattern portion is greater than a height of each of the second pattern portions.

9. The image sensor of claim 1, wherein a width of the first pattern portion is greater than a width of each of the second pattern portions, and
wherein a height of the first pattern portion is greater than a height of each of the second pattern portions.

10. The image sensor of claim 1, wherein the first material pattern is in contact with the second material pattern, and
the second material pattern comprises a side surface that is not vertically aligned with a side surface of the first material pattern.

11. The image sensor of claim 1, wherein the first material pattern is in contact with the second material pattern, and
a width of the second material pattern is greater than a width of the first material pattern.

12. The image sensor of claim 1, wherein the insulating structure comprises a first layer, a second layer, a third layer, and a fourth layer that are sequentially stacked,
wherein the first layer is an aluminum oxide layer,
each of the second and fourth layers is a hafnium oxide layer,
the third layer is a silicon oxide layer,
a thickness of the second layer is greater than a thickness of each of the first and fourth layers, and
a thickness of the third layer is greater than a thickness of the second layer.

13. The image sensor of claim 1, wherein the color filters comprise a first color filter of a first color, a second color filter of a second color that differs from the first color, and a third color filter of a third color that differs from the first and second colors,
the first pattern portion is disposed between color filters of different colors of the first to third color filters,
the first pattern portion comprises side surfaces opposite to each other,
the side surfaces of the first pattern portion are in contact with or adjacent to color filters of different colors,
each of the second pattern portions comprises side surfaces opposite to each other, and
side surfaces of any one second pattern portion are in contact with or adjacent to color filters of the same color.

14. The image sensor of claim 13, wherein the microlenses include a plurality of microlenses disposed on the first color filter, a plurality of microlenses disposed on the second color filter, and a plurality of microlenses disposed on the third color filter, and
each of the microlenses has a convex shape in a direction away from the first chip structure.

15. The image sensor of claim 1, wherein the first chip structure further includes:
a first circuit device and a first interconnection structure disposed on the first substrate, and
a first insulating layer disposed on the first substrate and that covers the first circuit device and the first interconnection structure,
wherein the second chip structure further includes:
a second circuit device and a second interconnection structure disposed between the first surface of the second substrate and the first chip structure; and
a second insulating layer disposed between the first surface of the second substrate and the first chip structure and that covers the second circuit device and the second interconnection structure.

16. The image sensor of claim 15, wherein the second chip structure further comprises:
a first reference region and a second reference region disposed in the second substrate;
separation structures disposed in the second substrate;
a light blocking pattern disposed on the insulating structure and that overlaps the first and second reference regions;
a first via hole that penetrates through the insulating structure, the second substrate, and the second insulating layer and extends into the first insulating layer, wherein the first via hole exposes a first pad of the first interconnection structure and a pad portion of the second interconnection structure;
a second via hole that penetrates through the insulating structure, the second substrate, and the second insulating layer and extends into the first insulating layer, wherein the second via hole is spaced apart from the second interconnection structure and exposes a second pad of the first interconnection structure;
a connection conductive layer disposed in the first via hole and that is electrically connected to the first pad of the first interconnection structure and the pad portion of the second interconnection structure; and
an input/output conductive layer disposed in the second via hole and that is electrically connected to the second pad of the second interconnection structure,
wherein the photoelectric conversion devices are disposed between the separation structures,
each of the photoelectric conversion devices in the first reference region comprises a photodiode,
the second reference region does not comprise a photodiode, and
the light blocking pattern comprises a conductive material layer and a blue color filter layer disposed on the conductive material layer.

17. An image sensor, comprising:
a substrate that includes a plurality of pixel regions;
an insulating structure disposed on the substrate and that includes a plurality of sequentially stacked layers;
a grid pattern structure disposed on the insulating structure;
color filters disposed on the insulating structure; and
microlenses disposed on the color filters,
wherein the grid pattern structure includes a first pattern portion and second pattern portions,
wherein when viewed in plan view,
the first pattern portion includes first horizontal straight portions parallel to each other, and first vertical straight portions that are parallel to each other and perpendicular to the first horizontal straight portions,
each of the second pattern portions includes a second horizontal straight portion parallel to the first horizontal straight portions, and a second vertical straight portion parallel to the first vertical straight portions, wherein
the second horizontal straight portion is perpendicular to the second vertical straight portion,
wherein the first pattern portion includes a first material pattern that contacts the insulating structure, and a second material pattern disposed on the first material pattern,
wherein the first material pattern is formed of a first material, and
the second material pattern and the second pattern portions are formed of a second material that differs from the first material.

18. The image sensor of claim 17, wherein the color filters comprise a first color filter of a first color, a second color filter of a second color that differs from the first color, and a third color filter of a third color that differs from the first and second colors,
the first pattern portion is disposed between color filters of different colors of the first to third color filters,
each of the second pattern portions comprises side surfaces opposite to each other,
the first pattern portion comprises side surfaces opposite to each other,
the side surfaces of the first pattern portion are in contact with or adjacent to color filters of different colors,
side surfaces of the one second pattern portions are in contact with or adjacent to color filters of the same color,
the microlenses include a plurality of microlenses disposed on the first color filter, a plurality of microlenses disposed on the second color filter, and a plurality of microlenses disposed on the third color filter, and
each of the microlenses has a convex shape in a direction away from the substrate.

19. An image sensor, comprising:
a substrate that including a plurality of first pixel regions, a plurality of second pixel regions, and a plurality of third pixel regions;
an insulating structure disposed on the substrate and that includes a plurality of sequentially stacked layers;
a grid pattern structure disposed on the insulating structure;
color filters disposed on the insulating structure; and
microlenses disposed on the color filters,
wherein the color filters include a first color filter of a first color, a second color filter of a second color that differs from the first color, and a third color filter of a third color that differs from the first and second colors,
the grid pattern structure includes a first pattern portion and second pattern portions,
the first pattern portion is disposed between color filters of different colors of the first to third color filters,
the first to third color filters cover side surfaces and an upper surface of the second pattern portions,
the microlenses include a plurality of microlenses disposed on the first color filter, a plurality of microlenses disposed on the second color filter, and a plurality of microlenses disposed on the third color filter, and
each of the second pattern portions is covered by any one of the first to third color filters,
wherein the first pattern portion includes a first material pattern and a second material pattern on the first material pattern,
the first material pattern includes a first material, and
the second material pattern and the second pattern portions include a second material that differs from the first material.

20. The image sensor of claim 19, wherein the first material comprises a conductive material,
the second material comprises an insulating material,
each of the plurality of first to third pixel regions comprises a photoelectric conversion device,
the first color filter overlaps the plurality of first pixel regions,
the second color filter overlaps the plurality of second pixel regions,
the third color filter overlaps the plurality of third pixel regions, and
a center of each of the microlenses does not overlap the second pattern portions.
